(19) United States
(12) Patent Application Publication
(10) Pub. No.: US 2025/0093391 A1
(43) Pub. Date: Mar. 20, 2025

(54) METHOD AND APPARATUS FOR SENSING CURRENT IN A BACK-TO-BACK CONFIGURATION

(71) Applicant: Microchip Technology Incorporated, Chadler, AZ (US)

(72) Inventors: Ehab Tarmoom, Allen Park, MI (US); Steven Chenetz, Gilbert, AZ (US); Xuning Zhang, Round Rock, TX (US); Ali Shahabi, Austin, TX (US); Robin L. Weber, Philadelphia, PA (US)

(73) Assignee: Microchip Technology Incorporated, Chandler, AZ (US)

(21) Appl. No.: 18/884,377

(22) Filed: Sep. 13, 2024

Related U.S. Application Data
(60) Provisional application No. 63/538,370, filed on Sep. 14, 2023.

(51) Int. Cl. G01R 19/00; G01R 1/20

(52) U.S. Cl. CPC G01R 19/0092; G01R 1/203

(57) ABSTRACT

An apparatus for sensing current in a back-to-back MOSFET configuration is provided. The apparatus may include a first MOSFET having a gate terminal, a drain terminal, and a source terminal, a second MOSFET having a source terminal coupled to the source terminal of the first MOSFET, a gate terminal, and a drain terminal, a gate driver circuit including at least one gate drive output terminal to output a gate drive signal to the gate terminals of the first and second MOSFETs, and a shunt resistor coupled between the source terminals of the first and second MOSFETs. The gate driver circuit may include a return terminal coupled to the source terminal of the first MOSFET, and a return current from the gate terminal of the second MOSFET flows through the shunt resistor to the return terminal of the gate driver circuit.

### CROSS-REFERENCE TO RELATED APPLICATION

The present application claims priority to U.S. Provisional Patent Application No. 63/538,370, filed on Sep. 14, 2023, the contents of which are hereby incorporated by reference in their entirety.

### TECHNICAL FIELD

The present disclosure relates generally to sensing current in a bi-directional circuit interruption device, and more specifically to sensing current in a back-to-back configuration.

### SUMMARY

According to an aspect of various examples, there is provided an apparatus for sensing current in a common-source MOSFET configuration using a shunt resistor coupled between the source terminals of two MOSFET devices, such as for example as an electronic fuse. The apparatus may include a first MOSFET having a gate terminal, a drain terminal, and a source terminal, a second MOSFET having a source terminal coupled to the source terminal of the first MOSFET, a gate terminal, and a drain terminal, a gate driver circuit including at least one gate drive output terminal to output a gate drive signal to the gate terminals of the first and second MOSFETs, and a shunt resistor coupled between the source terminals of the first and second MOSFETs. The gate driver circuit may include a return terminal that is coupled to the source terminal of the first MOSFET, and the gate return current from the gate terminal of the second MOSFET may flow through the shunt resistor to the return terminal of the gate driver circuit.

The gate driver circuit may include an input terminal to receive a control signal, and the gate driver circuit may output the gate drive signal based on the control signal. The drain terminal of the first MOSFET may be coupled to a voltage source, and the drain terminal of the second MOSFET may be coupled to a load. The voltage source may be an AC voltage source. The device may include an operational amplifier coupled to the shunt resistor to detect a voltage drop across the shunt resistor so as to detect current through the shunt resistor. The at least one gate drive output terminal may include a first output terminal and a second output terminal, and the first output terminal may be coupled to the second output terminal through respective gate driver output resistors to output the gate drive signal to the gate terminals of the first and second MOSFETs. The device may include a first gate resistor coupled between the gate terminal of the first MOSFET and the at least one gate drive output terminal, and a second gate resistor coupled between the gate terminal of the second MOSFET and the at least one gate drive output terminal. A resistance of the first gate resistor may be greater than a resistance of the second gate resistor. The device may include a first gate capacitor having a first terminal coupled to a common voltage, and a second terminal coupled between the gate terminal of the first MOSFET and the first gate resistor.

According to an aspect of various examples, there is provided a method of sensing current in a common-source MOSFET configuration using a shunt resistor coupled between the source terminals of two MOSFET devices. The method may include generating, by a gate driver circuit, a gate drive signal to drive a gate terminal of a first MOSFET and a gate terminal of a second MOSFET, forming a gate drive signal return path from a source terminal of the second MOSFET through a shunt resistor coupled between the source terminal of the second MOSFET and a source terminal of the first MOSFET, to a return terminal of the gate driver circuit, and sensing current through the shunt resistor.

The method may include receiving a control signal, such that the gate drive signal is generated based on the control signal. The method may include providing an input voltage to a drain terminal of the first MOSFET, and providing an output current to a load coupled to a second drain terminal of the second MOSFET. The input voltage may be an AC voltage, and the gate drive signal may cause the second MOSFET to turn on based on a polarity of the AC voltage. Sensing the current through the shunt resistor may include using an operational amplifier coupled to the shunt resistor to detect a voltage drop across the shunt resistor and output a signal corresponding to the current through the shunt resistor. The method may include turning on the second MOSFET before turning on the first MOSFET.

According to an aspect of various examples, there is provided an apparatus for sensing current in a common-source MOSFET configuration using a shunt resistor coupled between the source terminals of two MOSFET devices. The apparatus may include a first MOSFET having a gate terminal, a drain terminal, and a source terminal, a second MOSFET having a source terminal coupled to the source terminal of the first MOSFET, a gate terminal, and a drain terminal, a gate driver circuit including an input terminal to receive a control signal, and at least one gate drive output terminal to output a gate drive signal to the gate terminals of the first and second MOSFETs based on the control signal, a shunt resistor coupled between the source terminals of the first and second MOSFETs, a first gate resistor coupled between the gate terminal of the first MOSFET and the at least one gate drive output terminal, and a second gate resistor coupled between the gate terminal of the second MOSFET and the at least one gate drive output terminal. The gate driver circuit may include a return terminal coupled to the source terminal of the first MOSFET, and gate drive return current from the gate terminal of the second MOSFET flows through the shunt resistor to the return terminal of the gate driver circuit.

The drain terminal of the first MOSFET may be coupled to a voltage source, and the drain terminal of the second MOSFET may be coupled to a load. The voltage source may be an AC voltage source. The apparatus may include an operational amplifier coupled to the shunt resistor to detect a voltage drop across the shunt resistor so as to detect current through the shunt resistor. The at least one gate drive output terminal may include a first output terminal and a second output terminal, and the first output terminal may be coupled to the second output terminal through respective gate driver output resistors to output the gate drive signal to the gate terminals of the first and second MOSFETs.

### BRIEF DESCRIPTION OF DRAWINGS

FIG. 1 shows a circuit diagram of an apparatus for sensing current in a common-source MOSFET configuration according to various examples.

FIG. 2 shows a circuit diagram of an apparatus for sensing current in a common-source MOSFET configuration according to various examples.

FIG. 3 shows a circuit diagram of an apparatus for sensing current in a common-source MOSFET configuration according to various examples.

FIG. 4 shows a circuit diagram of a circuit for providing the control signal that is received by the gate driver circuit in FIG. 3 based on an AC power source according to various examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

Current sensing in a common-source MOSFET configuration is used in a variety of applications such as solid-state circuit breakers, electronic fuses, and solid-state relays. In a back-to-back MOSFET configuration a very low resistance shunt resistor may be used to sense current through the MOSFETs. However, coupling the shunt resistor, for example in a common-source configuration, where the source of a first MOSFET is coupled in series to the source of a second MOSFET, between the drain terminal of one of the MOSFETs and either the high voltage source or the load results in more circuit complexity and cost, and may also need an isolation interface to isolate the MOSFET's control and drive circuits from the high voltage source and the load, which may affect accuracy, response time, and/or bandwidth. Alternatively, when the common source terminals of the MOSFETs are respectively coupled to a return terminal of a gate driving circuit, placing the shunt resistor between the common source terminals of the MOSFETS will be ineffective because the path to the return terminal of the gate driving circuit shorts the shunt resistor, resulting in no current flowing through the shunt resistor. Although the foregoing discussion references MOSFETs in a common source configuration, it may also apply to multiple MOSFETs connected in parallel, and configurations using other devices such as insulated gate bipolar transistors (IGBTs). For example, each MOSFET in a common-source configuration may have one or more MOSFETs connected in parallel to share current. In this configuration, the respective source and drain terminals of the MOSFETs are connected, and the respective gate terminals may have respective gate resistors coupled to a gate driver circuit. Therefore, a device and method for sensing current through bi-directional circuit interruption devices without increasing the cost or complexity of the circuit, or negatively impacting bandwidth or response time, is needed.

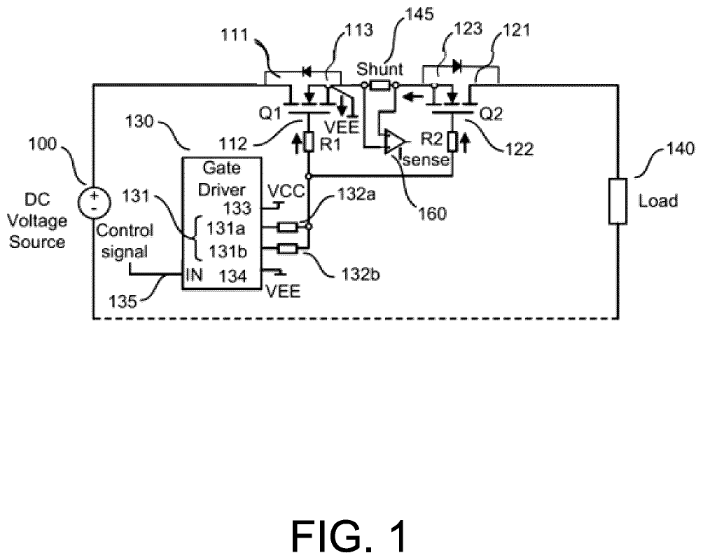

FIG. 1 shows a circuit diagram of a block diagram of an apparatus for sensing current in a back-to-back NMOSFET configuration according to various examples. While the figures may be particularly described in relation to an NMOSFET back-to-back configuration, this is not to be limiting in any way, and may be similarly applied to a PMOSFET or IGBT back-to-back configuration. The apparatus may include a first MOSFET Q1 having a drain terminal 111 that is coupled to a positive terminal of a DC voltage source 100, a gate terminal 112 coupled to a gate driver circuit 130, and a source terminal 113. The apparatus may also include a second MOSFET Q2 having a source terminal 123 coupled to the source terminal 113 of the first MOSFET Q1, a gate terminal 122 coupled to the gate driver circuit 130, and a drain terminal 121 coupled to a load 140. The device may include a shunt resistor 145 coupled between the source terminal 113 of the first MOSFET Q1 and the source terminal 123 of the second MOSFET Q2. For clarity, the respective body diodes of the first MOSFET Q1 and the second MOSFET Q2 are shown.

The gate driver circuit 130 may include a gate drive output terminal 131 that outputs a gate drive signal to the gate terminals 112, 122 of the first and second MOSFETs Q1, Q2. The gate drive output terminal 131 may include a first or high side output terminal 131a and a second or low side output terminal 131b, which may be coupled together through two gate driver output resistors 132a, 132b respectively coupled to the first and second output terminals 131a, 131b. The first output terminal may be driven high in a first active state, and the second output terminal may be driven low in a second active state, the first and second active states not overlapping. The gate driver output resistors 132a, 132b may be respectively coupled to gate terminal 112 of first MOSFET Q1 and gate terminal 122 of second MOSFET Q2, and may respectively affect the turn-on and turn-off times of the first MOSFET Q1 and the second MOSFET Q2. For example, gate driver output resistor 132a may increase the turn-on time of first and second MOSFETs Q1 and Q2. Gate driver output resistor 132b may increase the turn-off time of first and second MOSFETs Q1 and Q2. According to various examples, one or both of the gate driver output resistors 132a, 132b may be omitted. For example, gate driver output resistor 132a may be included and gate driver output resistor 132b may be omitted so that the turn-on time is greater than the turn-off time for first and second MOSFETs Q1 and Q2. The gate driver circuit 130 may include a power supply input VCC 133 and a return terminal 134 that may be coupled to a common voltage or ground. The gate driver circuit 130 may also have an input terminal IN 135 to receive a control signal. The gate drive signal may be output based on the received control signal.

The source terminal 113 of first MOSFET Q1 may be coupled to the return terminal 134 of the gate driver circuit 130, creating a return path for the gate drive signal from the gate drive output terminal 131 to the gate terminal 112, to the source terminal 113, and back to the return terminal 134 of the gate driver circuit 130. The return path for the gate drive signal for second MOSFET Q2 is from the gate drive output terminal 131 to the gate terminal 122, to the source terminal 123, through the shunt resistor 145, and back to the return terminal 134 of the gate driver circuit 130. By not coupling the source terminal 123 of the second MOSFET Q2 directly to the return terminal 134 of the gate driver circuit 130, output current for the load 140 flows through the shunt resistor 145, which allows the output current for the load 140 to be detected as a voltage drop across the shunt resistor 145. For example, a differential op-amp 160 may be coupled to both sides of the shunt resistor 145, so as to amplify a voltage drop across the shunt resistor 145, and output a signal Isense corresponding to the current through the shunt resistor 145. Both output current for the load 140 and the return current for the gate drive signal for second MOSFET Q2 flow through the shunt resistor 145, however the return current for the gate drive signal for second MOSFET Q2 is extremely small in relation to the current for the load 140, and thus can be neglected in any measurement of the signal Isense corresponding to the current through the shunt resistor 145.

According to various examples, the device may also include a first gate resistor R1 coupled between the gate terminal 112 of the first MOSFET Q1 and the gate drive output terminal 131, and a second gate resistor R2 coupled between the gate terminal 122 of the second MOSFET Q2 and the gate drive output terminal 131. The first and second gate resistors R1, R2 may be coupled to the gate drive output terminal 131 to receive the gate drive signal. According to various examples, the first gate resistor R1 may have a higher resistance than the second gate resistor R2, which may cause the second MOSFET Q2 to turn on before the first MOSFET Q1.

Although the example device shown in FIG. 1 shows the return path for the gate drive signal going through a node coupled to the source terminal 113 of the first MOSFET Q1, the return path may go through a node coupled to the source terminal 123 of the second MOSFET Q2 according to various examples. For example, not shown in FIG. 1, the source terminal 123 of the second MOSFET Q2 may be coupled to the return terminal 134 of the gate driver circuit 130, and the source terminal 113 of the first MOSFET Q1 is not directly coupled to the return terminal 134 of the gate driver circuit 130. In this example, a return path for the gate drive signal through the first MOSFET Q1 goes from the gate drive output terminal 131 to the gate terminal 112 of the first MOSFET Q1, to the source terminal 113 of the first MOSFET Q1, through the shunt resistor 145 and back to the return terminal 134 of the gate driver circuit 130. The return path for the gate drive signal for the second MOSFET Q2 is from the gate drive output terminal 131 to the gate terminal 122 of the second MOSFET Q2, to the source terminal 123 of the second MOSFET Q2, and back to the return terminal 134 of the gate driver circuit 130. In this example, the resistance of the second gate resistor R2 may be greater than the resistance of the first gate resistor R1, which may cause the first MOSFET Q1 to turn on before the second MOSFET Q2. Although the example shown in FIG. 1 includes MOSFET devices in a common source configuration, various examples may include multiple MOSFETs connected in parallel, or alternative devices such as IGBTs. For example, first MOSFET Q1 and second MOSFET Q2 may each have one or more MOSFETs connected in parallel to share current. In this configuration, the respective source and drain terminals of the MOSFETs are connected, and the respective gate terminals may have respective gate resistors coupled to the gate driver circuit 130.

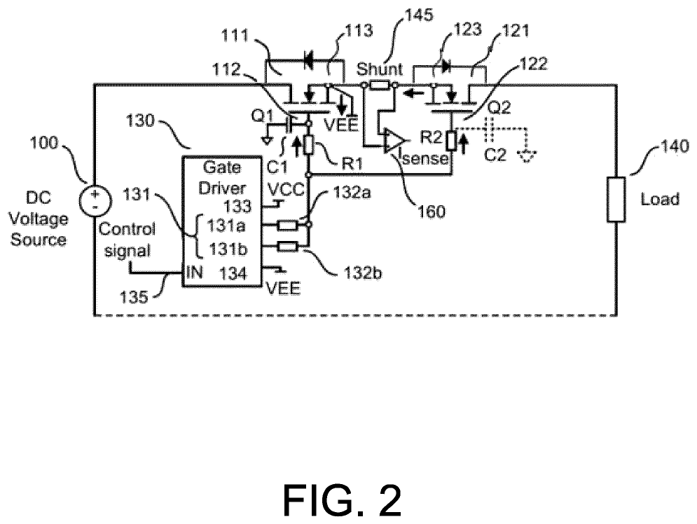

FIG. 2 shows a circuit diagram of a block diagram of an apparatus for sensing current in a back-to-back MOSFET configuration according to various examples. The device shown in FIG. 2 is similar to the device shown in FIG. 1, and some common components will not be described again here to avoid redundancy. The device shown in FIG. 2 may include a first gate capacitor C1 having a first terminal coupled to a common voltage or ground which may or may not be the same node coupled to the return terminal 134 of the gate driver circuit 130, and a second terminal coupled between the gate terminal 112 of the first MOSFET Q1 and the first gate resistor R1. In this example, the first and second gate resistors R1, R2 may have the same or different resistances. The first gate capacitor C1 may increase the RC time constant of the first MOSFET Q1, which may result in the second MOSFET Q2 turning on before the first MOSFET Q1. In various examples in which the return path to the gate driver circuit 130 is through a node coupled to the source terminal 123 of the second MOSFET Q2, the first gate capacitor C1 may be replaced by a second gate capacitor C2 coupled between the gate terminal 122 of the second MOSFET Q2 and the second gate resistor R2 to increase the RC time constant of the second MOSFET Q2 so that the first MOSFET Q1 turns on before the second MOSFET Q2.

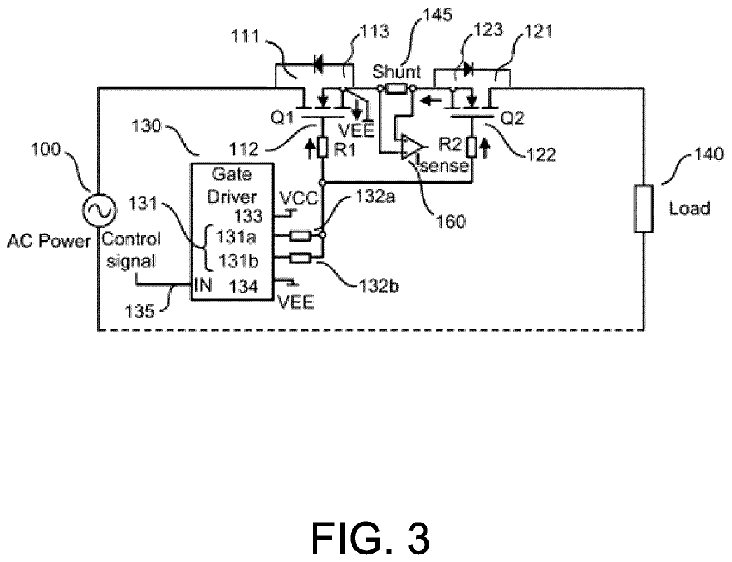

FIG. 3 shows a circuit diagram of a block diagram of an apparatus for sensing current in a back-to-back MOSFET configuration according to various examples. The device shown in FIG. 3 is similar to the devices shown in FIGS. 1 and 2, and some common components will not be described again here to avoid redundancy. The device shown in FIG. 3 is coupled to an AC power source 300, such as an AC voltage source, as opposed to the DC voltage source 100 of FIGS. 1 and 2. When the device is coupled to the AC power source 300, the control signal provided to the gate driver circuit 130 may turn on the gate driver circuit 130 when the AC power is positive, which may result in the gate driver circuit 130 outputting a gate drive signal when the output of the AC power coupled to the first drain terminal 111 is positive in respect to the output of the AC power coupled to the second drain terminal 121 through the load 140. According to various examples, the gate driver circuit 130 may not output a gate drive signal to turn on the gate driver circuit when the output of the AC power coupled to the first drain terminal 111 is negative in respect to the output of the AC power coupled to the second drain terminal 121 through the load 140.

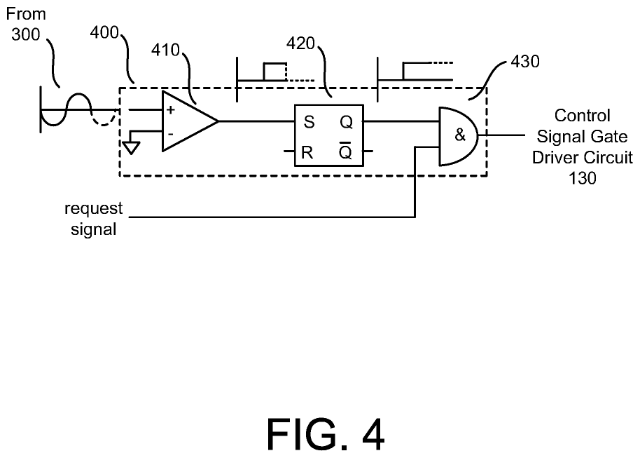

FIG. 4 shows a circuit diagram of a circuit for providing the control signal that is received by the gate driver circuit 130 in FIG. 3 based on an AC power source according to various examples. The circuit 400 for providing the control signal to the gate driver circuit 130 may include a comparator 410 to receive at its first input terminal, which may be a non-inverting input terminal, an AC signal from AC power source 300. The second input terminal, which may be an inverting input terminal, of the comparator 410 may be coupled to ground. The comparator 410 may generate an output signal based on a comparison between the AC signal received from the AC power source 300 at the non-inverting input terminal, and ground. More specifically, when the AC signal is negative, the comparator 410 generates a first logic output, e.g., a logic low output, and when the AC signal is positive, the comparator 410 generates a second logic output, e.g., a logic high output. The output of the comparator 410 is output to a Set-input of an S-R latch 420. The S-R latch 420 passes the output of the comparator 410 from the Set-input to a Q-output of the S-R latch 420. For example, when the output of the comparator 410 changes from a logic low level to a logic high level, the S-R latch 420 outputs a logic high signal at the Q-output. As shown in FIG. 4, the Reset input of the S-R latch is used to reset the Q-output of the S-R latch 420 to a logic low level. The S-R latch 420 also includes an inverted Q-output, which outputs the inverted signal of the Q-output. In the example shown in FIG. 4, the inverted Q-output is not used. According to various examples, prior to switching the request signal (discussed below) from a logic low state to a logic high state, a reset signal (e.g., an active-high pulse) may be supplied to the Reset input by a controller (not shown) so that the Q-output of the S-R latch 420 becomes logic low. The Q-output of the S-R latch 420 will switch to a logic high state when the AC signal has a positive polarity following the end of the reset signal supplied to the Reset input, as explained further below.

The Q-output of the S-R latch 420 is coupled to a first input terminal of an AND gate 430. The AND gate 430 includes a second input terminal that receives the request signal, and generates a logic high output when the output of the Q-output of the S-R latch 420 and the request signal are logic high. The request signal may be provided by several sources depending on implementation. For example, the request signal may be provided by a controller that commands the gate driver circuit 130 to turn on the first and second MOSFETs Q1, Q2. The controller may be implement in, without limitation, a microcontroller unit, field programmable gate array, or discrete hardware circuit. The controller may also control the state of the Reset-input of the S-R latch 420. In examples that use a DC voltage source, such as in FIGS. 1 and 2, the request signal may be the control signal provided to the input terminal 135 of the gate driver circuit.

In the example of FIG. 4, the output of the AND gate 430 is the control signal that is input to the input terminal 135 of the gate driver circuit 130 in FIG. 3. As described above, the gate driver circuit 130 outputs the gate drive signal to turn on the first and second MOSFETS Q1 and Q2 based on the control signal. The circuit 400 of FIG. 4 generates the control signal based on the polarity of the AC power source, which means that the gate driver circuit 130 outputs a gate drive signal to turn on the first and second MOSFETS Q1 and Q2 based on the polarity of the signal output from the AC power source 300, e.g., the control signal is asserted, i.e. high, when both the request signal is active high and the polarity of the AC power source is positive, and the control signal is deasserted, i.e. low, when the request signal is deasserted, i.e. low, or the polarity of polarity of the AC power source is not positive (e.g., negative). In one example, as a startup condition, it is important that Q2 be turned on first followed by Q1, and this is to occur when polarity is positive, so as to avoid large current flow through any of the body diodes of MOSFET Q1 or Q2. Thus, a controller may clear the S-R latch 420 immediately before asserting the request signal to ensure that the control signal to get driver circuit 130 is asserted when the signal from the AC power source 300 next turns positive. Upon overload, detected by the controller responsive to signal Isense output by differential op-amp 160, the controller may deassert the request signal thereby disabling (opening) MOSFETs Q1 and Q2.

Various examples have been disclosed herein, in connection with the above description and the drawings. It will be understood that it would be unduly repetitious to literally describe and illustrate every combination and subcombination of these examples. Accordingly, all examples can be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. An apparatus for sensing current in a back-to-back MOSFET configuration, the apparatus comprising:
a first MOSFET having a gate terminal, a drain terminal, and a source terminal;
a second MOSFET having a source terminal coupled to the source terminal of the first MOSFET, a second gate terminal, and a second drain terminal;
a gate driver circuit including at least one gate drive output terminal to output a gate drive signal to the gate terminals of the first and second MOSFETs; and
a shunt resistor coupled between the source terminals of the first and second MOSFETs;
wherein the gate driver circuit includes a return terminal coupled to the source terminal of the first MOSFET; and
wherein a return current from the gate terminal of the second MOSFET flows through the shunt resistor to the return terminal of the gate driver circuit.

2. The apparatus of claim 1, wherein the gate driver circuit includes an input terminal to receive a control signal; and
wherein the gate driver circuit is to output the gate drive signal based on the control signal.

3. The apparatus of claim 1, wherein the drain terminal of the first MOSFET is to be coupled to a voltage source, and the drain terminal of the second MOSFET is to be coupled to a load.

4. The apparatus of claim 3, wherein the voltage source is an AC voltage source.

5. The apparatus of claim 1, comprising an operational amplifier coupled to the shunt resistor to detect a voltage drop across the shunt resistor so as to detect current through the shunt resistor.

6. The apparatus of claim 1, wherein the at least one gate drive output terminal includes a first output terminal and a second output terminal; and
wherein the first output terminal is coupled to the second output terminal through at least one respective gate driver output resistor to output the gate drive signal to the gate terminals of the first and second MOSFETs.

7. The apparatus of claim 1, comprising:
a first gate resistor coupled between the gate terminal of the first MOSFET and the at least one gate drive output terminal; and
a second gate resistor coupled between the gate terminal of the second MOSFET and the at least one gate drive output terminal.

8. The apparatus of claim 6, wherein a resistance of the first gate resistor is greater than a resistance of the second gate resistor.

9. The apparatus of claim 6, comprising a first gate capacitor having a first terminal coupled to a common voltage, and a second terminal coupled between the gate terminal of the first MOSFET and the first gate resistor.

10. A method of sensing current in a back-to-back MOSFET configuration, the method comprising:
generating, by a gate driver circuit, a gate drive signal to drive a gate terminal of a first MOSFET and a gate terminal of a second MOSFET;
forming a gate drive signal return path from a source terminal of the second MOSFET through a shunt resistor coupled between the source terminal of the second MOSFET and a source terminal of the first MOSFET, to a return terminal of the gate driver circuit; and
sensing current through the shunt resistor.

11. The method of claim 10, comprising receiving a control signal;
wherein the gate drive signal is generated based on the control signal.

12. The method of claim 10, comprising:
providing an input voltage to a drain terminal of the first MOSFET; and
providing an output current to a load coupled to a drain terminal of the second MOSFET.

13. The method of claim 12, wherein the input voltage is an AC voltage, and
wherein the gate drive signal causes the second MOSFET to turn on based on a polarity of the AC voltage.

14. The method of claim 10, wherein the sensing the current through the shunt resistor includes using an operational amplifier coupled to the shunt resistor to detect a voltage drop across the shunt resistor and output a signal corresponding to the current through the shunt resistor.

15. An apparatus for sensing current in a back-to-back MOSFET configuration, the apparatus comprising:
a first MOSFET having a gate terminal, a drain terminal, and a source terminal;
a second MOSFET having a source terminal coupled to the source terminal of the first MOSFET, a gate terminal, and a drain terminal;
a gate driver circuit including an input terminal to receive a control signal, and at least one gate drive output terminal to output a gate drive signal to the gate terminals of the first and second MOSFETs based on the control signal;
a shunt resistor coupled between the source terminals of the first and second MOSFETS;
a first gate resistor coupled between the gate terminal of the first MOSFET and the at least one gate drive output terminal; and
a second gate resistor coupled between the gate terminal of the second MOSFET and the at least one gate drive output terminal;
wherein the gate driver circuit includes a return terminal coupled to the source terminal of the first MOSFET; and
wherein gate drive return current from the gate terminal of the second MOSFET flows through the shunt resistor to the return terminal of the gate driver circuit.

16. The apparatus of claim 15, wherein the drain terminal of the first MOSFET is to be coupled to a voltage source, and the drain terminal of the second MOSFET is to be coupled to a load.

17. The apparatus of claim 16, wherein the voltage source is an AC voltage source.

18. The apparatus of claim 15, comprising an operational amplifier coupled to the shunt resistor to detect a voltage drop across the shunt resistor so as to detect current through the shunt resistor.

19. The apparatus of claim 15, wherein the at least one gate drive output terminal includes a first output terminal and a second output terminal; and
wherein the first output terminal is coupled to the second output terminal through respective gate driver output resistors to output the gate drive signal to the gate terminals of the first and second MOSFETs.
